(19) United States
(12) Patent Application Publication
(10) Pub. No.: US 2026/0286203 A1
(43) Pub. Date: Sep. 24, 2026

(54) CMP SLURRY COMPOSITION FOR POLISHING COPPER LAYER AND METHOD FOR POLISHING COPPER LAYER USING THE SAME

(71) Applicant: SAMSUNG SDI CO., LTD., Yongin-si (KR)

(72) Inventors: Jung Hwa LEE, Suwon-si (KR); Soo Yeon SIM, Suwon-si (KR); Kyoung Soo PARK, Suwon-si (KR); Hye Youn JANG, Suwon-si (KR); Se I MOON, Suwon-si (KR); Hye In KIM, Suwon-si (KR); Kun Bae NOH, Suwon-si (KR)

(73) Assignee: SAMSUNG SDI CO., LTD., Yongin-si (KR)

(21) Appl. No.: 19/551,227

(22) Filed: Feb. 26, 2026

(30) Foreign Application Priority Data
Mar. 20, 2025 (KR) 10-2025-0035941

(51) Int. Cl. C09K 3/14; H10P 52/40

(52) U.S. Cl. CPC C09K 3/1463; H10P 52/403

(57) ABSTRACT

Disclosed herein are a CMP slurry composition for polishing a copper layer, and a method of polishing a copper layer using the copper layer. The CMP slurry composition includes at least one solvent from a polar solvent and a nonpolar solvent, an abrasive agent, and a corrosion inhibitor. The corrosion inhibitor includes a mixture of a first corrosion inhibitor and a second corrosion inhibitor. The first corrosion inhibitor includes a triazole based compound. The second corrosion inhibitor includes a pyrazine based or triazine based compound, substituted with at least one substituted or unsubstituted amino group or at least one substituted or unsubstituted aminoalkyl group.

### CROSS-REFERENCE TO RELATED APPLICATION

The present application claims priority and the benefit of Korean Patent Application No. 10-2025-0035941, filed on Mar. 20, 2025 in the Korean Intellectual Property Office, the entire disclosure of which is incorporated herein by reference.

### FIELD OF THE DISCLOSURE

The present disclosure relates to a chemical mechanical polishing (CMP) slurry composition for polishing a copper layer and a method of polishing a copper layer using the same.

### DESCRIPTION OF THE RELATED ART

In light of the trend towards higher integration and performance in semiconductor integrated circuits, CMP (chemical mechanical polishing) has emerged as a microfabrication technology frequently used in planarization of interlayer dielectric films, formation of metal plugs, and formation of embedded interconnects. In addition, copper and copper alloys are notable conductive materials recently employed in interconnect applications. Due to lower resistance thereof than aluminum and other metals, copper or copper alloys offer the advantage of significantly improving the performance of integrated circuits.

A CMP composition for polishing a copper layer may achieve a high polishing rate, desired or improved polishing selectivity for copper over barrier metals or dielectrics, high planarization, and reduced defects upon copper film polishing. To achieve these objectives, a corrosion inhibitor is used to control corrosion of a copper layer.

### SUMMARY

It is an aspect of the present disclosure to provide a CMP slurry composition for polishing a copper layer, which can polish a copper layer at a high polishing rate, can reduce erosion of the polished copper layer, and can improve flatness of a polished surface of the copper layer.

In accordance with one aspect of the present disclosure, a CMP slurry composition for polishing a copper layer includes at least one solvent including one of a polar solvent and a nonpolar solvent; an abrasive agent, and a corrosion inhibitor. The corrosion inhibitor includes a mixture of a first corrosion inhibitor and a second corrosion inhibitor, the first corrosion inhibitor includes a triazole based compound, and the second corrosion inhibitor includes a pyrazine based or triazine based compound, substituted with at least one substituted or unsubstituted amino group or at least one substituted or unsubstituted aminoalkyl group.

In accordance with another aspect of the present disclosure, a method of polishing a copper layer includes polishing a copper layer using the CMP slurry composition according to the present disclosure.

Example embodiments of the present disclosure include a CMP slurry composition for polishing a copper layer, which can polish a copper layer at a high polishing rate, can reduce erosion of the polished copper layer, and can improve flatness of a polished surface of the copper layer.

### DETAILED DESCRIPTION

Hereinafter, example embodiments of the present disclosure are described in detail such that the present disclosure can be readily implemented by a person having ordinary knowledge in the art. It should be understood that the present disclosure may be embodied in different ways, and is not limited to the following example embodiments.

The terminology used herein is for the purpose of describing example embodiments and is not intended to limit the present disclosure. As used herein, the singular forms “a”, “an”, and “the” are intended to include the plural forms as well, unless the context clearly indicates otherwise.

As used herein, “substituted” in “substituted or unsubstituted” means that at least one hydrogen atom in a corresponding functional group is substituted with one of a hydroxyl group, a C₁ to C₁₀ alkyl group or haloalkyl group, a C₂ to C₁₀ alkenyl group or haloalkenyl group, a C₂ to C₁₀ alkynyl group or haloalkynyl group, a C₃ to C₁₀ cycloalkyl group, a C₃ to C₁₀ cycloalkenyl group, a C₆ to C₁₀ aryl group, a C₇ to C₁₀ arylalkyl group, a C₁ to C₁₀ alkoxy group, a C₆ to C₁₀ aryloxy group, an amino group, a halogen group, a cyano group, or a thiol group.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

In accordance with one aspect of the present disclosure, a CMP slurry composition for polishing a copper layer includes at least one solvent including one of a polar solvent and a nonpolar solvent, an abrasive agent, and a corrosion inhibitor. The corrosion inhibitor includes a mixture of a first corrosion inhibitor and a second corrosion inhibitor. The first corrosion inhibitor is a triazole based compound. The second corrosion inhibitor is a pyrazine based or triazine based compound, substituted with at least one substituted or unsubstituted amino group or at least one substituted or unsubstituted aminoalkyl group.

The triazole based compound may be used as a corrosion inhibitor in CMP slurry compositions for polishing copper layers. However, the triazole based compound has a strong corrosion inhibition effect on a copper layer and thus can adversely affect the flatness of a polished surface of the copper layer. Through combined use of the first corrosion inhibitor and the second corrosion inhibitor, the CMP slurry composition according to the present disclosure can ensure reduced erosion of a polished copper layer and improved flatness of a polished surface of the copper layer while maintaining a high polishing rate with respect to the copper layer.

Below, each component of the CMP slurry composition according to one example embodiment is described in detail.

### Solvent

The at least one solvent including one of a polar solvent and a nonpolar solvent reduces friction upon polishing a copper layer with the abrasive agent. The at least one solvent may include water (for example, ultrapure water or deionized water), organic amines, organic alcohols, organic alcohol amines, organic ethers, organic ketones, and the like. For example, ultrapure water or deionized water is used as the solvent.

The at least one solvent may be present in the balance amount, for example, in an amount in a range of about 30 wt % to about 99 wt %, in the CMP slurry composition.

### Abrasive Agent

The abrasive agent may include a typical abrasive agent used for polishing. For example, the abrasive agent may include metal or non-metal oxide abrasive particles. The abrasive agent may include, for example, at least one of silica including colloidal silica, fumed silica, and the like, alumina, ceria, titania, and zirconia. In one example embodiment, the abrasive agent may include silica (for example, colloidal silica), without being limited thereto.

The abrasive agent includes spherical or non-spherical particles, and may have an average primary particle diameter (D₅₀) in a range of about 10 nm to about 150 nm, for example, 20 nm to 70 nm. Within the above range, a high polishing rate with respect to a copper layer can be achieved, scratch defects can be reduced or prevented, and flatness of a polished surface can be improved. Herein, “average particle diameter (D₅₀)” is a typical particle diameter measure known in the art, and refers to a particle diameter of the abrasive particles corresponding to 50 vol % when the abrasive particles are distributed in order from smallest to largest in terms of volume.

The abrasive agent may be subjected to surface modification, or may not be subjected to surface modification. Surface-modified abrasive particles can have further improved dispersion stability in the CMP slurry composition, or can achieve a further enhanced polishing rate.

Surface modification of the abrasive agent may be performed by treating the abrasive agent with a surface modifying compound. In one example embodiment, the surface modifying compound may include a silane compound. When the abrasive agent is silica, the silane compound can facilitate surface modification of the abrasive agent. The silane compound may include at least one of mercapto group-containing alkoxysilanes, amino group-containing alkoxysilanes, tetraalkoxysilanes, and alkyl group-containing alkoxysilanes having a C₁ to C₁₀ alkyl group, without being limited thereto. In another example embodiment, silica as the abrasive agent may be subjected to primary surface modification with a compound having a sulfonate group or a phosphate group, and then may be subjected to a secondary surface modification with an alkoxysilane (for example, tetraethoxysilane).

The abrasive agent may be present in an amount in a range of about 0.001 wt % to about 20 wt %, for example 0.005 wt % to 10 wt %, for example 0.01 wt % to 5 wt %, and for example 0.05 wt % to 3 wt %, in the CMP slurry composition. Within the above range, a sufficient polishing rate with respect to a copper layer can be achieved, scratch defects can be reduced or prevented, and dispersion stability of the abrasive agent in the composition can be improved.

### Corrosion Inhibitor

The CMP slurry composition includes a corrosion inhibitor.

The corrosion inhibitor may be present in an amount in a range of about 0.001 wt % to about 1 wt %, for example 0.005 wt % to 1 wt %, and for example 0.01 wt % to 0.5 wt %, in the CMP slurry composition. Within the above range, the corrosion inhibitor can reduce dishing of a copper layer upon polishing while ensuring a high polishing rate with respect to the copper layer.

The corrosion inhibitor includes a mixture of a first corrosion inhibitor and a second corrosion inhibitor.

A copper layer polishing composition containing only the first corrosion inhibitor without the second corrosion inhibitor can adversely affect flatness of a polished surface of a copper layer due to a strong corrosion inhibition effect thereof on the copper layer. Conversely, a copper layer polishing composition containing only the second corrosion inhibitor without the first corrosion inhibitor can be ineffective at removing irregularities on a surface of the copper layer.

The first corrosion inhibitor includes a triazole based compound.

In one example embodiment, the triazole based compound may include at least one of a compound represented by Formula 1 or a compound represented by Formula 2.

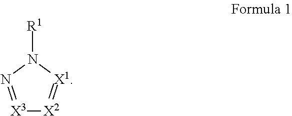

In Formula 1, R¹ is hydrogen, a substituted or unsubstituted C₁ to C₈ alkyl group, or a substituted or unsubstituted C₆ to C₁₀ aryl group, and

X¹ to X³ each independently is or includes a nitrogen atom or C—R, R being hydrogen, a substituted or unsubstituted C₁ to C₅ alkyl group, or a substituted or unsubstituted C₆ to C₁₀ aryl group, provided that one of X¹ to X³ is a nitrogen atom.

In one example embodiment, R¹ is hydrogen or a substituted or unsubstituted C₁ to C₅ alkyl group, for example, hydrogen or a methyl group.

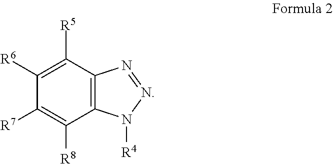

In Formula 2, R⁴ to R⁸ are each independently hydrogen, a hydroxyl group, or a substituted or unsubstituted C₁ to C₆ alkyl group.

In one example embodiment, the first corrosion inhibitor may include at least one compound represented by Formula 1-1:

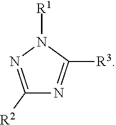

R¹ is as defined in Formula 1, and

R² and R³ are each independently hydrogen or a substituted or unsubstituted C₁ to C₅ alkyl group.

For example, R¹ to R³ may be or include hydrogen or a methyl group.

For example, the first corrosion inhibitor may include at least one benzotriazole compound such as or including at least one of 1,2,4-triazole, 1,2,3-triazole, benzotriazole, methyl benzotriazole (tolyltriazole) including 5-methylbenzotriazole, such as 5-methyl-1H-benzotriazole, 4-methylbenzotriazole, and the like, ethyl benzotriazole, propyl benzotriazole, butyl benzotriazole, pentyl benzotriazole, hexyl benzotriazole, hydroxy benzotriazole, and the like, without being limited thereto.

For example, the first corrosion inhibitor includes at least one of 1,2,4-triazole or 1,2,3-triazole.

The first corrosion inhibitor may be present in an amount in a range of about 0.0001 wt % to about 1 wt %, for example, 0.0001 wt % to 0.5 wt %, 0.0005 wt % to 0.5 wt %, or 0.01 wt % to 0.3 wt %, in the CMP slurry composition. Within the above range, the CMP slurry composition can polish a copper layer at a high polishing rate while providing a corrosion inhibition effect on the copper layer.

The second corrosion inhibitor includes a pyrazine based or triazine based compound, substituted with at least one substituted or unsubstituted amino group or at least one substituted or unsubstituted aminoalkyl group.

In this disclosure, “amino group” refers to —NH₂.

In this disclosure, “substituted or unsubstituted amino group” may refer to an unsubstituted amino group or an alkyl-substituted amino group.

In this disclosure, “substituted or unsubstituted aminoalkyl group” may refer to an unsubstituted aminoalkyl group or an alkyl-substituted aminoalkyl group.

In one example embodiment, the second corrosion inhibitor may include a pyrazine based or triazine based compound, substituted with 1 to 4 substituted or unsubstituted amino groups or 1 to 4 substituted or unsubstituted aminoalkyl groups.

In one example embodiment, the second corrosion inhibitor may include at least one compound represented by Formula 3:

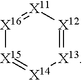

In Formula 3, X¹¹ to X¹⁶ are each independently a nitrogen atom, C—R, or C—R′,
provided that X¹¹ and X¹⁴ are each a nitrogen atom and at least one of X¹², X¹³, X¹⁵ and X¹⁶ is C—R, or
three of X¹¹ to X¹⁶ are each a nitrogen atom and at least one of the remaining three is C—R,
R is a compound represented by Formula 3-1:

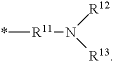

* is a linking site to an element,
R¹¹ is a single bond or a substituted or unsubstituted C₁ to C₅ alkylene group, and
R¹² and R¹³ are each independently hydrogen or a substituted or unsubstituted C₁ to C₅ alkyl group), and
R′ is hydrogen, a halogen, a substituted or unsubstituted C₁ to C₅ alkyl group, or a substituted or unsubstituted C₆ to C₁₀ aryl group.

Here, “halogen” may be F, Cl, Br, or I.

In one example embodiment, in Formula 3, X¹¹ and X¹⁴ may each be a nitrogen atom, one of X¹², X¹³, X¹⁵, and X¹⁶ may be C—R, and the remaining three may all be C—R′.

In another example embodiment, in Formula 3, three of X¹¹ to X¹⁶ may each be a nitrogen atom, one of the remaining three may be C—R, and the remaining two may all be C—R′.

For example, in Formula 3, X¹¹ to X¹³ may each be a nitrogen atom, one of X¹⁴ to X¹⁶ may be C—R, and the remaining two may all be C—R′.

For example, in Formula 3, X¹¹, X¹², and X¹⁴ may each be a nitrogen atom, one of X¹³, X¹⁵, and X¹⁶ may be C—R, and the remaining two may all be C—R′.

For example, in Formula 3, X¹¹, X¹³, and X¹⁵ may each be a nitrogen atom, one of X¹², X¹⁴, and X¹⁶ may be C—R, and the remaining two may all be C—R′.

In Formula 3-1, R¹¹ may be or include a single bond or a methylene group, and R¹² and R¹³ may be each independently hydrogen or an unsubstituted C₁ to C₅ alkyl group.

In Formula 3, R′ may be hydrogen, a halogen, or a substituted or unsubstituted C₁ to C₅ alkyl group.

For example, the second corrosion inhibitor may include at least one compound represented by Formula 3-2:

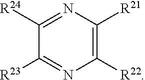

R²¹ to R²⁴ are each independently hydrogen, a halogen, a substituted or unsubstituted C₁ to C₈ alkyl group, a substituted or unsubstituted C₆ to C₁₀ aryl group, or the compound represented by Formula 3-1, provided that at least one of R²¹ to R²⁴ is the compound represented by Formula 3-1.

For example, in Formula 3-2, R²¹ may be or include the compound represented by Formula 3-1, and R²² to R²⁴ may be or include each independently hydrogen, a halogen, or a substituted or unsubstituted C₁ to C₅ alkyl group.

For example, in Formula 3-2, R²¹ may be or include the compound represented by Formula 3-1, and R²² to R²⁴ may be or include each independently hydrogen or a halogen. For example, R²² to R²⁴ may all be hydrogen, or R²² and R²⁴ may be each independently hydrogen and R²³ may be or include a halogen.

The second corrosion inhibitor may be synthesized by a typical method known to those skilled in the art.

The second corrosion inhibitor may be present in an amount in a range of about 0.0001 wt % to about 1 wt %, for example, 0.0001 wt % to 0.5 wt %, 0.0005 wt % to 0.3 wt %, 0.001 wt % to 0.3 wt %, or 0.001 wt % to 0.1 wt %, in the CMP slurry composition. Within the above range, the CMP slurry composition can polish a copper layer at a high polishing rate, can reduce erosion of the polished copper layer, and can improve flatness of a polished surface of the copper layer.

In one example embodiment, the first corrosion inhibitor and the second corrosion inhibitor may be present in a weight ratio in a range of about 1:0.1 to about 1:10, for example, 1:0.1 to 1:5, 1:0.1 to 1:3, or 1:0.3 to 1:2, in the composition. Within the above range, the CMP slurry composition can be significantly effective at polishing a copper layer at a high polishing rate, reducing erosion of the polished copper layer, and improving flatness of a polished surface of the copper layer.

The CMP slurry composition according to the present disclosure may further include a dishing inhibitor.

### Dishing Inhibitor

The dishing inhibitor may include a mixture of polyvinyl alcohol and a copolymer of acrylic acid and acrylamide.

Through use of a mixture of polyvinyl alcohol and a copolymer of acrylic acid and acrylamide as the dishing inhibitor, in combination with the mixture of the first corrosion inhibitor and the second corrosion inhibitor, the CMP slurry composition according to the present disclosure can be significantly effective at polishing a copper layer at a high polishing rate, reducing erosion of the polished copper layer, and improving flatness of a polished surface of the copper layer.

The copolymer of acrylic acid and acrylamide may include a copolymer of a monomer mixture including acrylic acid and acrylamide, as represented by Formula 4:

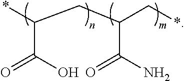

* is a linking site to an element, and
each of n and m is the number of moles of a corresponding repeat unit.

In one example embodiment, acrylic acid and acrylamide may be present in a mole ratio in a range of about 1:30 to about 30:1 in the monomer mixture. Within the above range, the dishing inhibitor can inhibit dishing without reduction in polishing rate with respect to a copper layer. For example, the mole ratio of acrylic acid to acrylamide may be 5:95 to 95:5, for example, 10:90 to 80:20, 50:50 to 80:20, or 70:30, based on the total mole number of acrylic acid and acrylamide.

In one example embodiment, the copolymer of acrylic acid and acrylamide may have a weight average molecular weight (Mw) in a range of about 600,000 g/mol to about 2,000,000 g/mol, for example, 1,000,000 g/mol to 2,000,000 g/mol, or 1,000,000 g/mol to 1,500,000 g/mol. Within the above range, the dishing inhibitor can inhibit dishing and erosion without reduction in polishing rate with respect to a copper layer.

Herein, “weight average molecular weight” may be determined by gel permeation chromatography using pullulan as a molecular weight standard reagent and an aqueous mobile phase.

The copolymer of acrylic acid and acrylamide may be present in an amount in a range of about 0.0001 wt % to about 5 wt %, for example, 0.0001 wt % to 3 wt %, 0.0005 wt % to 1 wt %, or 0.001 wt % to 1 wt %, in the CMP slurry composition. Within the above range, the dishing inhibitor can inhibit dishing and erosion without reduction in polishing rate with respect to a copper layer.

The polyvinyl alcohol may include a polymer of vinyl alcohol.

The polyvinyl alcohol may have a weight average molecular weight (Mw) of 600,000 g/mol to 2,000,000 g/mol, for example, 1,000,000 g/mol to 2,000,000 g/mol, or 1,000,000 g/mol to 1,500,000 g/mol. Within the above range, the dishing inhibitor can inhibit dishing and erosion without reduction in polishing rate with respect to a copper layer.

The polyvinyl alcohol may present in an amount in a range of about 0.0001 wt % to about 1 wt %, for example, 0.0001 wt % to 0.5 wt %, 0.0005 wt % to 0.1 wt %, or 0.001 wt % to 0.1 wt %, in the CMP slurry composition. Within the above range, the dishing inhibitor can inhibit dishing and erosion without reduction in polishing rate with respect to a copper layer.

The copolymer of acrylic acid and acrylamide and the polyvinyl alcohol are required to be present in an appropriate ratio. In one example embodiment, the copolymer and the polyvinyl alcohol may be present in a weight ratio in a range of about 1:1 to about 50:1, for example, 5:1 to 50:1, or 10:1 to 30:1. Within the above range, the dishing inhibitor can reduce defects, such as dishing and erosion, without reduction in polishing rate with respect to a copper layer.

The dishing inhibitor may be present in an amount in a range of about 0.0001 wt % to about 5 wt %, for example, 0.001 wt % to 5 wt %, 0.001 wt % to 3 wt %, or 0.001 wt % to 1 wt %, in the CMP slurry composition. Within the above range, the dishing inhibitor can reduce defects, such as dishing and erosion, without reduction in polishing rate with respect to a copper layer.

In some example embodiments, the CMP slurry composition may further include at least one of an oxidizing agent, a complexing agent, and a pH adjuster.

The oxidizing agent can facilitate polishing of a copper layer by oxidizing the copper layer and can ensure good surface roughness after polishing by leveling the surface of the copper layer.

The oxidizing agent may include at least one of an inorganic per-compound, an organic per-compound, bromic acid or salts thereof, nitric acid or salts thereof, chloric acid or salts thereof, chromic acid or salts thereof, iodic acid or salts thereof, iron or salts thereof, copper or salts thereof, a rare-earth metal oxide, a transition metal oxide, and potassium dichromate. Herein, “per-compound” refers to a compound containing at least one peroxide group (—O—O—) or containing an element in the highest oxidation state. For example, the oxidizing agent includes a per-compound. For example, the per-compound may include at least one of hydrogen peroxide, potassium periodate, calcium persulfate, and potassium ferricyanide, for example hydrogen peroxide.

The oxidizing agent may be present in an amount in a range of about 0.01 wt % to about 5 wt %, for example 0.05 wt % to 4 wt %, and for example 0.1 wt % to 3 wt %, in the CMP slurry composition. Within the above range, the oxidizing agent can improve polishing selectivity for a copper layer.

The complexing agent further enhances a polishing rate with respect to a copper layer.

The complexing agent may include a typical complexing agent known to those skilled in the art. For example, the complexing agent may include at least one of amino acids (for example, glycine), imidazole, ammonia, amino alcohols, polyamines, polyhydric alcohols (for example, dihydric alcohols, trihydric alcohols, ethylene glycol, pyrocatechol, pyrogallol, and the like), carbonyl compounds (for example, acetylacetonate and the like), simple carboxylic acids and salts thereof (for example, acetic acid and salts thereof, arylcarboxylic acid and salts thereof, and the like), carboxylic acids containing one or more hydroxyl groups and salts thereof (for example, glycolic acid and salts thereof, lactic acid and salts thereof, gluconic acid and salts thereof, gallic acid and salts thereof, and the like), di-, tri-, or polycarboxylic acids and salts thereof (for example, oxalic acid and salts thereof, phthalic acid and salts thereof, citric acid and salts thereof, succinic acid and salts thereof, tartaric acid and salts thereof, malic acid and salts thereof, EDTA and salts thereof (for example, dipotassium EDTA), mixtures thereof, and the like), carboxylic acids containing one or more sulfonic acid groups and/or phosphonic acid groups and salts thereof, di-, tri- or polyhydric alcohols (for example, ethylene glycol, pyrocatechol, pyrogallol, tannic acid, and the like), and amine-containing compounds (for example, ammonia, amino acids, amino alcohols, di-, tri-, and polyamines, and the like), without being limited thereto.

The complexing agent may be present in an amount in a range of about 0.01 wt % to about 5 wt %, for example 0.05 wt % to 5 wt %, and for example 0.1 wt % to 5 wt %, in the CMP slurry composition. Within the above range, the complexing agent can enhance a polishing rate with respect to a copper layer and dispersion stability of abrasive particles in slurry while improving surface characteristics of a polished copper layer.

The CMP slurry composition may have a pH in a range of about 5 to about 9, for example 6 to 8. Within the above range, corrosion of a copper layer can be reduced or prevented.

The CMP slurry composition may further include a pH adjuster to adjust the pH of the composition to the above range. In one example embodiment, the pH adjuster may include an inorganic acid, for example, at least one of nitric acid, phosphoric acid, hydrochloric acid, and sulfuric acid, and/or an organic acid, for example, an organic acid having a pKₐ of 6 or less, for example, at least one of acetic acid and phthalic acid. In another example embodiment, the pH adjuster may include a base, for example, at least one of sodium hydroxide, potassium hydroxide, ammonium hydroxide, sodium carbonate, and potassium carbonate.

The CMP slurry composition may further include at least one biocide such as or including at least one of a pesticide and a germicide to inhibit microbial growth and/or contamination. Each of the pesticide and the germicide may include a material commonly used in CMP slurry compositions to achieve the aforementioned purpose.

The CMP slurry composition may further include typical additives, such as surfactants, dispersants, modifiers, and the like.

In accordance with another aspect of the present disclosure, a method of polishing a copper layer includes polishing a copper layer using the CMP slurry composition according to the present disclosure.

Next, the present disclosure is described in more detail with reference to some examples. It should be understood that these examples are provided for illustration only and are not to be construed in any way as limiting the present disclosure.

Details of components used in Examples and Comparative Examples were as follows.
a. Abrasive agent: Colloidal silica (NP60, average particle size: 50 nm)
b. Complexing agent: Glycine
c.
First corrosion inhibitor: 1,2,4-triazole
Second corrosion inhibitor 1: Aminopyrazine
Second corrosion inhibitor 2:2-amino-5-bromopyrazine
Pyrazine
d.
Dishing inhibitor 1: Copolymer of acrylic acid and acrylamide (mole ratio (based on total 10 mol): 7:3, weight average molecular weight: 1,300,000 g/mol).
Dishing inhibitor 2: Polyvinyl alcohol (weight average molecular weight: 1,300,000 g/mol).
e. Oxidizing agent: Hydrogen peroxide
f. pH adjuster: Nitric acid or potassium hydroxide

### Example 1

A CMP slurry composition was prepared by mixing 0.2 wt % of the abrasive agent, 1.5 wt % of the complexing agent, 0.16 wt % of the first corrosion inhibitor, 0.05 wt % of second corrosion inhibitor 1, 0.5 wt % of dishing inhibitor 1, 0.02 wt % of dishing inhibitor 2, and the balance of ultrapure water, based on the total weight of the CMP slurry composition. The CMP slurry composition was adjusted to pH of 7.3 using a pH adjuster. Thereafter, 1.00 wt % of hydrogen peroxide (liquid, Dongwoo Fine-Chem Co. Ltd.) as an oxidizing agent was added, thereby preparing a CMP slurry composition for property evaluation shown in Table 1 below.

### Example 2

A CMP slurry composition was prepared in the same manner as in Example 1 except that 0.16 wt % of the first corrosion inhibitor and 0.24 wt % of second corrosion inhibitor 2 were used instead of using 0.16 wt % of the first corrosion inhibitor and 0.05 wt % of second corrosion inhibitor 1 as in Example 1.

### Example 3

A CMP slurry composition was prepared in the same manner as in Example 1 except that 0.05 wt % of second corrosion inhibitor 2 was used instead of using 0.05 wt % of second corrosion inhibitor 1 as in Example 1.

### Example 4

A CMP slurry composition was prepared in the same manner as in Example 3 except that 0.16 wt % of the first corrosion inhibitor and 0.44 wt % of second corrosion inhibitor 2 were used instead of using 0.16 wt % of the first corrosion inhibitor and 0.05 wt % of second corrosion inhibitor 2 as in Example 3.

### Comparative Example 1

A CMP slurry composition was prepared in the same manner as in Example 1 except that 0.21 wt % of the first corrosion inhibitor was used instead of using 0.16 wt % of the first corrosion inhibitor and 0.05 wt % of second corrosion inhibitor 1 as in Example 1.

### Comparative Example 2

A CMP slurry composition was prepared in the same manner as in Example 1 except that 0.16 wt % of the first corrosion inhibitor and 0.05 wt % of pyrazine were used instead of using 0.16 wt % of the first corrosion inhibitor and 0.05 wt % of second corrosion inhibitor 1 as in Example 1.

### Comparative Example 3

A CMP slurry composition was prepared in the same manner as in Example 1 except that 0.21 wt % of second corrosion inhibitor 1 was used instead of using 0.16 wt % of the first corrosion inhibitor and 0.05 wt % of second corrosion inhibitor 1 as in Example 1.

Each of the CMP slurry compositions prepared in Examples and Comparative Examples was evaluated as to the following properties.
(1) Copper layer polishing rate (unit: Å/min): A copper layer was polished on a 300 mm polisher (AMAT Co., Ltd.) using an IC₁₀₁₀ polishing pad (Rodel Inc.) under the same conditions: a platen speed of 93 rpm, a head speed of 87 rpm, a down pressure of 1.5 psi, a slurry flow rate of 150 ml/min, and a polishing time of 60 seconds. The polishing rate with respect to the copper layer was calculated by converting the difference in resistance measured before and after polishing into the difference in layer thickness before and after polishing.
(2) Post-polishing surface roughness of copper layer (unit: nm): A copper layer was polished in the same manner as in (1), followed by measurement of surface roughness of the polished copper layer using an atomic force microscope (AFM).
(3) Copper layer etch rate (unit: Å): A copper specimen was dipped in a polishing solution, followed by measurement of the difference in layer thickness before and after the dipping process.

TABLE 1

| | Examples | | | | Comparative Examples | | |
|---|---|---|---|---|---|---|---|
| | 1 | 2 | 3 | 4 | 1 | 2 | 3 |
| Abrasive | 0.2 | 0.2 | 0.2 | 0.2 | 0.2 | 0.2 | 0.2 |
| agent | | | | | | | |
| Complexing | 1.5 | 1.5 | 1.5 | 1.5 | 1.5 | 1.5 | 1.5 |
| agent | | | | | | | |
| First | 0.16 | 0.16 | 0.16 | 0.16 | 0.21 | 0.16 | 0 |
| corrosion | | | | | | | |
| inhibitor | | | | | | | |
| Second | 0.05 | 0.24 | 0 | 0 | 0 | 0 | 0.21 |
| corrosion | | | | | | | |
| inhibitor 1 | | | | | | | |
| Second | 0 | 0 | 0.05 | 0.44 | 0 | 0 | 0 |
| corrosion | | | | | | | |
| inhibitor 2 | | | | | | | |
| Pyrazine | 0 | 0 | 0 | 0 | 0 | 0.05 | 0 |
| Dishing | 0.5 | 0.5 | 0.5 | 0.5 | 0.5 | 0.5 | 0.5 |
| inhibitor 1 | | | | | | | |
| Dishing | 0.02 | 0.02 | 0.02 | 0.02 | 0.02 | 0.02 | 0.02 |
| inhibitor 2 | | | | | | | |
| Ultrapure | Balance | Balance | Balance | Balance | Balance | Balance | Balance |
| water | | | | | | | |
| Polishing | 8,267 | 7,913 | 8,160 | 7,784 | 8,284 | 8,423 | 9,132 |
| rate | | | | | | | |
| Surface | 1.79 | 1.81 | 1.66 | 1.64 | 3.81 | 3.01 | 7.35 |
| roughness | | | | | | | |
| Etch rate | 915 | 896 | 877 | 773 | 1,031 | 963 | 1,457 |

As shown in Table 1 above, the CMP slurry compositions according to the present disclosure, prepared using both the first corrosion inhibitor and the second corrosion inhibitor, demonstrated improved corrosion inhibition performance, as compared to the CMP slurry composition prepared using the first corrosion inhibitor alone, the CMP slurry composition prepared using the second corrosion inhibitor alone, and the CMP slurry composition prepared using the first corrosion inhibitor and pyrazine. In addition, the CMP slurry compositions according to the present disclosure could minimize reduction in polishing rate while improving flatness of a polished surface in the polishing tests.

It should be understood that various modifications, changes, alterations, and equivalent example embodiments can be made by those skilled in the art without departing from the spirit and scope of the disclosure.

What is claimed is:

1. A CMP slurry composition for polishing a copper layer, the CMP slurry composition comprising:
at least one solvent comprising one of a polar solvent and a nonpolar solvent;
an abrasive agent; and
a corrosion inhibitor;
wherein the corrosion inhibitor comprises a mixture of a first corrosion inhibitor and a second corrosion inhibitor,
the first corrosion inhibitor comprises a triazole based compound, and
the second corrosion inhibitor comprises a pyrazine based or triazine based compound, substituted with at least one substituted or unsubstituted amino group or at least one substituted or unsubstituted aminoalkyl group.

2. The CMP slurry composition as claimed in claim 1, wherein the second corrosion inhibitor comprises at least one compound represented by Formula 3: 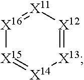
wherein X¹¹ to X¹⁶ each independently comprises a nitrogen atom, C—R, or C—R′,
provided that X¹¹ and X¹⁴ each comprises a nitrogen atom and at least one of X¹², X¹³, X¹⁵, and X¹⁶ comprises C—R, or
three of X¹¹ to X¹⁶ each comprises a nitrogen atom and at least one of the remaining three is C—R,
R is a compound represented by Formula 3-1: 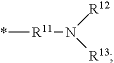
wherein * is a linking site to an element,
R¹¹ is a single bond or a substituted or unsubstituted C₁ to C₅ alkylene group, and
R¹² and R¹³ are each independently hydrogen or a substituted or unsubstituted C₁ to C₅ alkyl group, and
R′ is hydrogen, a halogen, a substituted or unsubstituted C₁ to C₅ alkyl group, or a substituted or unsubstituted C₆ to C₁₀ aryl group.

3. The CMP slurry composition as claimed in claim 2, wherein, in Formula 3, X¹¹ and X¹⁴ are each a nitrogen atom, one of X¹², X¹³, X¹⁵, and X¹⁶ is C—R, and the remaining three are all C—R′.

4. The CMP slurry composition as claimed in claim 2, wherein, in Formula 3, three of X¹¹ to X¹⁶ are each a nitrogen atom, one of the remaining three is C—R, and the remaining two are all C—R′.

5. The CMP slurry composition as claimed in claim 2, wherein, in Formula 3, X¹¹ to X¹³ are each a nitrogen atom, one of X¹⁴ to X¹⁶ is C—R, and the remaining two are all C—R′.

6. The CMP slurry composition as claimed in claim 2, wherein, in Formula 3, X¹¹, X¹², and X¹⁴ are each a nitrogen atom, one of X¹³, X¹⁵, and X¹⁶ is C—R, and the remaining two of are all C—R′.

7. The CMP slurry composition as claimed in claim 2, wherein, in Formula 3, X¹¹, X¹³, and X¹⁵ are each a nitrogen atom, one of X¹², X¹⁴, and X¹⁶ is C—R, and the remaining two are all C—R′.

8. The CMP slurry composition as claimed in claim 2, wherein, in Formula 3-1, R¹¹ is a single bond or a methylene group, and R¹² and R¹³ are each independently hydrogen or an unsubstituted C₁ to C₅ alkyl group.

9. The CMP slurry composition as claimed in claim 2, wherein the second corrosion inhibitor comprises at least one compound represented by Formula 3-2: 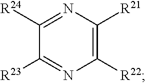
wherein R²¹ to R²⁴ are each independently hydrogen, a halogen, a substituted or unsubstituted C₁ to C₅ alkyl group, a substituted or unsubstituted C₆ to C₁₀ aryl group, or the compound represented by Formula 3-1, provided that at least one of R²¹ to R²⁴ is the compound represented by Formula 3-1.

10. The CMP slurry composition as claimed in claim 2, wherein the second corrosion inhibitor comprises at least one of aminopyrazine or aminobromopyrazine.

11. The CMP slurry composition as claimed in claim 1, wherein:
the first corrosion inhibitor is present in an amount in a range of about 0.0001 wt % to about 1 wt % in the CMP slurry composition; and
the second corrosion inhibitor is present in an amount in a range of about 0.0001 wt % to about 1 wt % in the CMP slurry composition.

12. The CMP slurry composition as claimed in claim 1, wherein the first corrosion inhibitor comprises at least one compound represented by Formula 1-1: 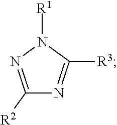
wherein R¹ comprises hydrogen, a substituted or unsubstituted C₁ to C₈ alkyl group, or a substituted or unsubstituted C₆ to C₁₀ aryl group, and
R² and R³ each independently comprises hydrogen or a substituted or unsubstituted C₁ to C₅ alkyl group.

13. The CMP slurry composition as claimed in claim 1, wherein the first corrosion inhibitor and the second corrosion inhibitor are present in a weight ratio in a range of about 1:0.1 to about 1:10 in the CMP slurry composition.

14. The CMP slurry composition as claimed in claim 1, further comprising:
a dishing inhibitor,
wherein the dishing inhibitor comprises a mixture of polyvinyl alcohol and a copolymer of acrylic acid and acrylamide.

15. The CMP slurry composition as claimed in claim 14, wherein:
the copolymer of acrylic acid and acrylamide is present in an amount in a range of about 0.0001 wt % to about 5 wt % in the CMP slurry composition; and
the polyvinyl alcohol is present in an amount in a range of about 0.0001 wt % to about 1 wt % in the CMP slurry composition.

16. The CMP slurry composition as claimed in claim 14, wherein the copolymer and the polyvinyl alcohol are present in a weight ratio in a range of about 1:1 to about 50:1.

17. The CMP slurry composition as claimed in claim 1, wherein the CMP slurry composition has a pH in a range of about 5 to about 9.

18. The CMP slurry composition as claimed in claim 1, the CMP slurry composition comprising:
a range of about 0.001 wt % to about 20 wt % of the abrasive agent;
a range of about 0.001 wt % to about 1 wt % of the corrosion inhibitor;
a range of about 0.0001 wt % to about 5 wt % of a dishing inhibitor; and
a range of about 0.01 wt % to about 5 wt % of a complexing agent.

19. The CMP slurry composition as claimed in claim 18, further comprising:
at least one additive comprising at least one of an oxidizing agent, a pH adjuster, and a biocide.

20. A method of polishing a copper layer, comprising:
polishing a copper layer using the CMP slurry composition as claimed in claim 1.
